(19) United States
(12) Patent Application Publication
(10) Pub. No.: US 2020/0109468 A1
(43) Pub. Date: Apr. 9, 2020

(54) VACUUM PROCESS APPARATUS AND VACUUM PROCESS METHOD

(71) Applicant: CREATING NANO TECHNOLOGIES, INC., TAINAN CITY (TW)

(72) Inventor: Ming-Yueh CHUANG, Tainan City (TW)

(21) Appl. No.: 16/595,496

(22) Filed: Oct. 8, 2019

(30) Foreign Application Priority Data
Oct. 8, 2018 (TW) 107135447

(51) Int. Cl. C23C 14/56; C23C 14/24

(52) U.S. Cl. CPC C23C 14/566; C23C 14/24

(57) ABSTRACT

A vacuum process apparatus includes a process chamber, a load lock, a carrier, a process device, and an evacuating device. The process chamber has an opening. The load lock is disposed on the process chamber. The carrier includes a first carrying surface and a second carrying surface opposite to the first carrying surface. The carrier is reversibly disposed on the opening to seal the process chamber and to position the first carrying surface and the second carrying surface in the process chamber and load lock respectively. The first carrying surface and the second carrying surface are configured to carry a first object and a second object to be treated. The process device is disposed within the process chamber and is configured to provide chemical reactants. The evacuating device is configured to perform an evacuating operation on the load lock while a vacuum process is performed within the process chamber.

### RELATED APPLICATIONS

This application claims priority to Taiwan Application Serial Number 107135447, filed Oct. 8, 2018, which is herein incorporated by reference.

### BACKGROUND

### Field of Invention

The present invention relates to an industrial process apparatus. More particularly, the present invention relates to a vacuum process apparatus.

### Description of Related Art

Generally, in order to enhance quality of a vacuum process, a process environment in a vacuum process apparatus needs to meet a condition of low fine dust and high cleanliness. In order to meet the requirements of low fine dust and high cleanliness, the vacuum process apparatus usually adopts dual chamber configuration, in which one is a process chamber, and the other one is a load lock. The process chamber is used to perform a vacuum process, such that the process chamber is usually in a vacuum state. The load lock is used to transport and replace objects to be treated, such as wafers or work pieces desiring a process, such as a deposition process or a coating process, such that the load lock is usually in an atmospheric environment.

Referring to FIG. 1A through FIG. 1E, FIG. 1A through FIG. 1E are schematic diagrams showing a flow of a vacuum process method performed in a conventional vacuum process apparatus. As shown in FIG. 1A, a conventional vacuum process apparatus 100 includes a process chamber 110, a load lock 120, a platform 130, and a transfer device 140. The process chamber 110 has an opening 112 disposed in a sidewall of the process chamber 110. The process chamber 110 further includes a door 114, in which the door 114 can cover the opening 112 of the process chamber 110. The load lock 120 is disposed beside the door 114. When the door 114 is opened, the process chamber 110 communicates with the load lock 120 through the opening 112. The load lock 120 has a door 122, in which the door 122 is disposed to cover an upper side of the load lock 120. The platform 130 is disposed within the process chamber 110 and is used to support an object 150 to be treated during a vacuum process. The transfer device 140 is disposed within the load lock 120, and can carry the object 150 to be treated, load the object 150 to be treated out of the process chamber 110 from the platform 130, load the object 150 to be treated into the process chamber 110 from the load lock 120, and dispose the object 150 to be treated on the platform 130.

When a vacuum process is performed by using the vacuum process apparatus 100, the door 114 of the process chamber 110 is closed to seal the process chamber 110. The process chamber 110 is evacuated. Then, as shown in FIG. 1A, the object 150 to be treated is disposed on the transfer device 140 in the load lock 120, and then the door 122 of the load lock 120 is closed.

Next, as shown in FIG. 1B, the load lock 120 is evacuated to make an inner of the load lock 120 be in a vacuum state. The load lock 120 and the process chamber 110 are both in the vacuum state, such that the door 114 of the process chamber 110 can be opened without relieving the vacuum of the process chamber 110. As shown in FIG. 1C, after the door 114 is opened, the transfer device 140 may load the object 150 to be treated into the process chamber 110 through the opening 112 and dispose the object 150 to be treated on the platform 130. Then, the transfer device 140 returns to the load lock 120. After the door 114 of the process chamber 110 is closed, the vacuum process is performed on the object 150 to be treated within the process chamber 150.

After the vacuum process of the object 150 to be treated is completed, the door 114 of the process chamber 110 is opened, and the object 150 to be treated on the platform 130 is loaded out of the process chamber 110 through the opening 112 and is disposed in the load lock 120 by using the transfer device 140. Subsequently, as shown in FIG. 1D, the door 114 of the process chamber 110 is closed to seal the process chamber 110. Now, as shown in FIG. 1E, the door 122 of the load lock 120 is opened to take the object 150 to be treated on which the vacuum process is completed out of the load lock 120. Then, another object 150 to be treated is disposed on the transfer device 140 of the load lock 120, and the vacuum process of this object 150 to be treated is performed according to the aforementioned procedure.

In such a vacuum process method, after the vacuum process of the vacuum 150 to be treated within the process chamber 110 is completed, the object 150 to be treated needs to be loaded out of the process chamber 110 by using the transfer device 140 in the load lock 120, such that the door 122 of the load lock 120 cannot be opened during the vacuum process of the object 150 to be treated, and thus a preparation operation of a next object 150 to be treated cannot be performed simultaneously. Accordingly, the vacuum process method has poor efficiency and is time-consuming, thus being disadvantageous for mass production.

### SUMMARY

Therefore, one objective of the present invention is to provide a vacuum process apparatus and a vacuum process method, in which a reversibly carrier is disposed between a process chamber and a load lock, and the carrier has two opposite carrying surfaces and can carry two objects to be treated simultaneously. Thus, when a vacuum process is performed on the object to be treated which is carried by one side of the carrier within the process chamber, the object to be treated on which the vacuum process is completed may be loaded out of the load lock, another object to be treated may be loaded into the load lock, and an evacuating operation may be performed on the load lock. Therefore, a preparation operation of a next object to be treated may be simultaneously performed during the vacuum process of one object to be treated, thereby greatly enhancing process efficiency and effectively increasing throughput.

According to the aforementioned objectives, the present invention provides a vacuum process apparatus. The vacuum process apparatus includes a process chamber, a load lock, a carrier, a process device, and an evacuating device. The process chamber has an opening. The load lock is disposed on the process chamber. The carrier includes a first carrying surface and a second carrying surface, which is opposite to the first carrying surface. The carrier is reversibly disposed on the opening to seal the process chamber, to position one of the first carrying surface and the second carrying surface in the process chamber, and to position the other one of the first carrying surface and the second carrying surface in the load lock. The first carrying surface and the second carrying surface are configured to respectively carry a first object to be treated and a second object to be treated. The process device is disposed within the process chamber and is configured to provide chemical reactants within the process chamber. The evacuating device is configured to perform an evacuating operation on the load lock while a vacuum process is performed within the process chamber.

According to one embodiment of the present invention, the load lock includes a door disposed on a side of the load lock.

According to one embodiment of the present invention, the process device is a deposition device.

According to one embodiment of the present invention, the process device is an evaporation device.

According to the aforementioned objectives, the present invention further provides a vacuum process method. In this vacuum process method, a vacuum process apparatus is provided. The vacuum process apparatus includes a process chamber, a load lock, and a carrier. The process chamber has an opening. The load lock is disposed on the process chamber. The carrier includes a first carrying surface and a second carrying surface, which is opposite to the first carrying surface. The carrier is disposed to cover the opening to seal the process chamber. A first object to be treated is disposed on the first carrying surface. The carrier is reversed to position the first carrying surface within the process chamber. A vacuum process is performed on the first object to be treated within the process chamber. During the vacuum process, a second object to be treated is disposed on the second carrying surface. A first evacuating operation is performed on the load lock. After the vacuum process is completed, the carrier is reversed to make the second object to be treated enter the process chamber under a vacuum state and to make the first object to be treated enter the load lock.

According to one embodiment of the present invention, the load lock includes a door disposed on a side of the load lock for the first object to be treated and the second object to be treated being loaded in and loaded out of the load lock.

According to one embodiment of the present invention, after reversing the carrier, the vacuum process method further includes performing the vacuum process on the second object to be treated. During performing the vacuum process on the second object to be treated, the door is opened and the first object to be treated is loaded out. During performing the vacuum process on the second object to be treated, a third object to be treated is loaded and is disposed on the first carrying surface. The first evacuating operation is performed on the load lock.

According to one embodiment of the present invention, performing the vacuum process on the first object to be treated includes performing a second evacuating operation on the process chamber, and using a process device to provide chemical reactants.

According to one embodiment of the present invention, the vacuum process is a deposition process.

According to one embodiment of the present invention, the vacuum process is an evaporation process.

### BRIEF DESCRIPTION OF THE DRAWINGS

The invention can be more fully understood by reading the following detailed description of the embodiment, with reference made to the accompanying drawings as follows:

FIG. 1A through FIG. 1E are schematic diagrams showing a flow of a vacuum process method performed in a conventional vacuum process apparatus;

FIG. 2A through FIG. 2D are schematic diagrams showing a flow of a vacuum process method performed in a vacuum process apparatus in accordance with an embodiment of the present invention; and

FIG. 3 is a flow chart of a vacuum process method in accordance with an embodiment of this invention.

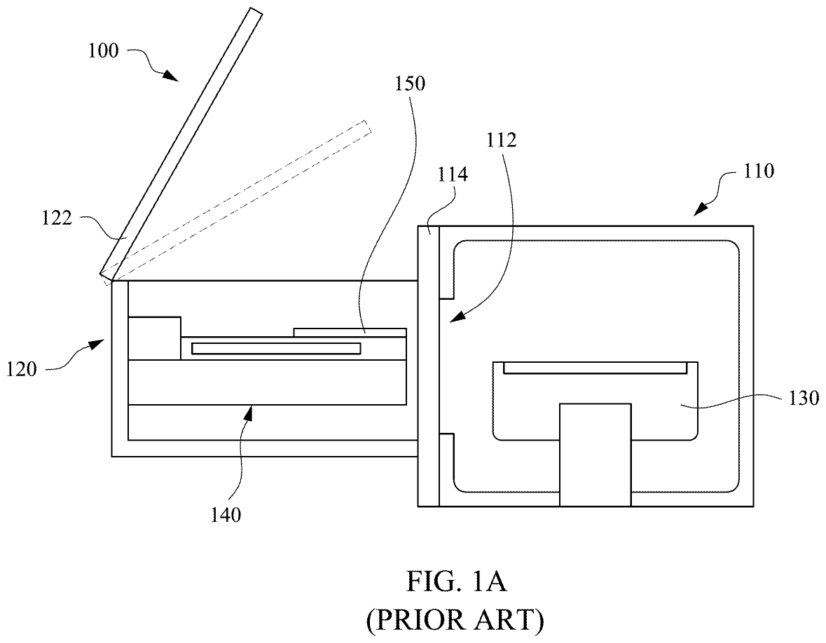

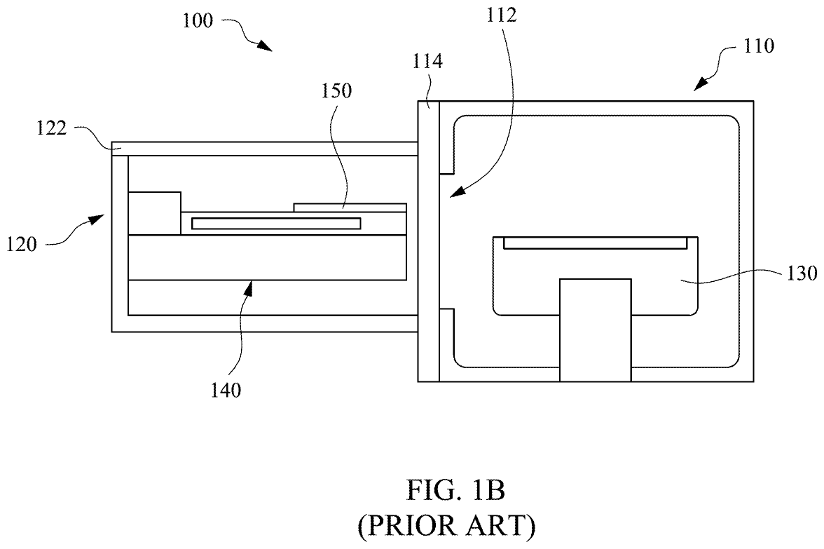

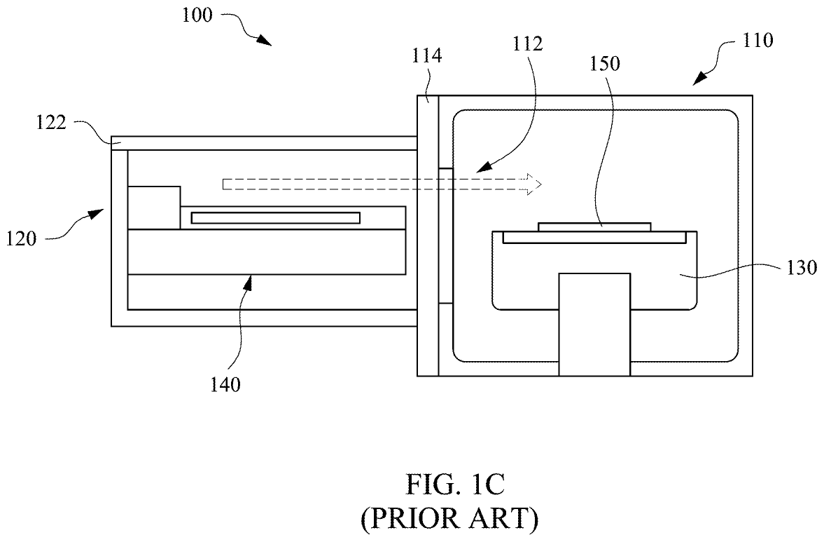

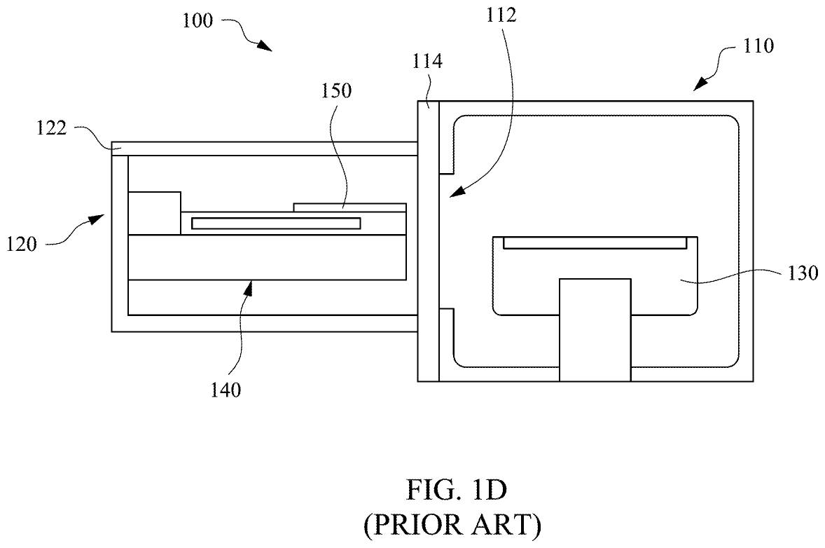

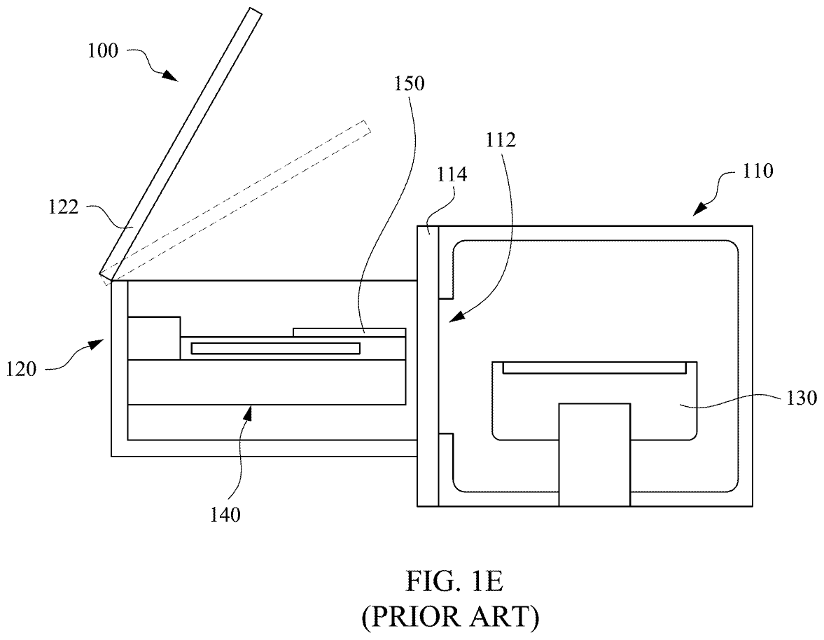

### DETAILED DESCRIPTION

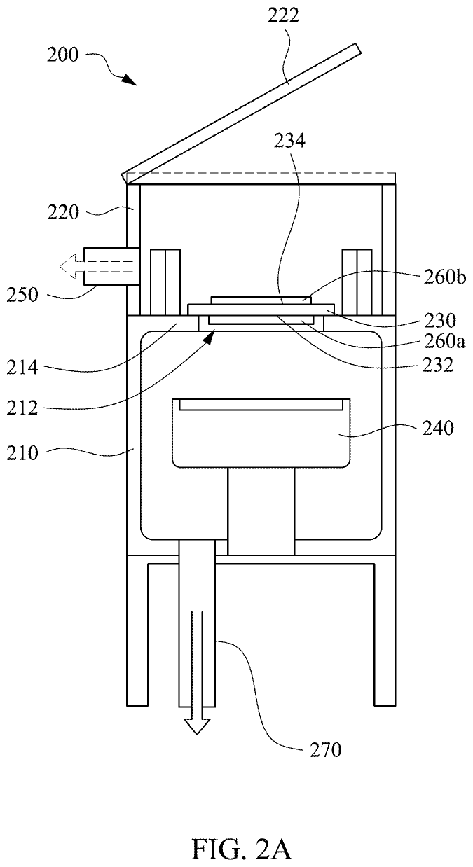

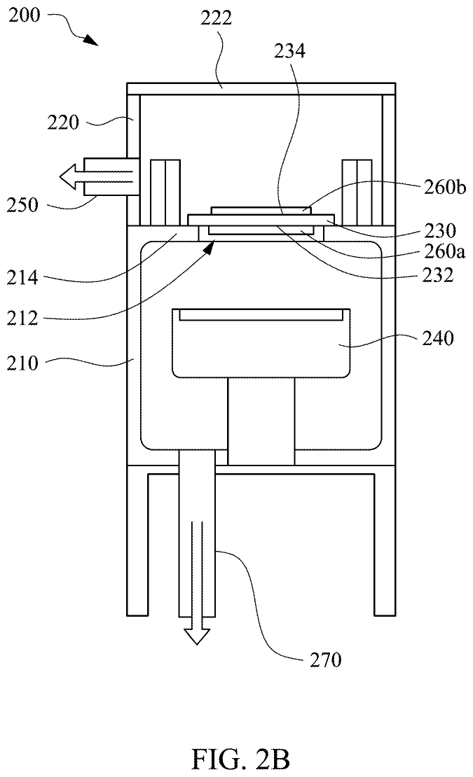

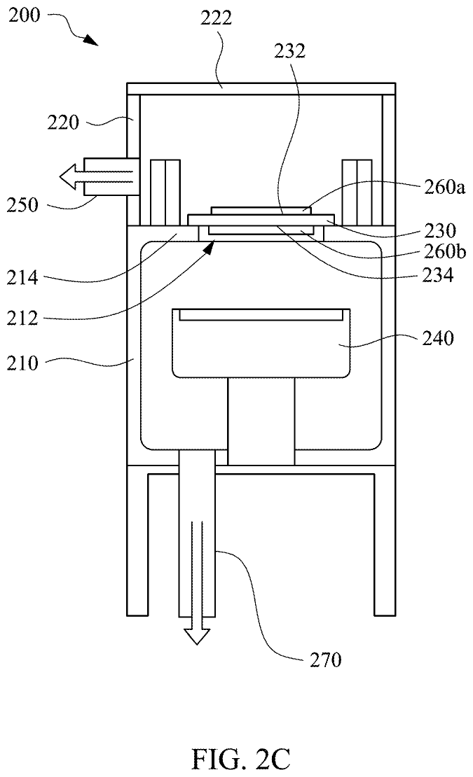

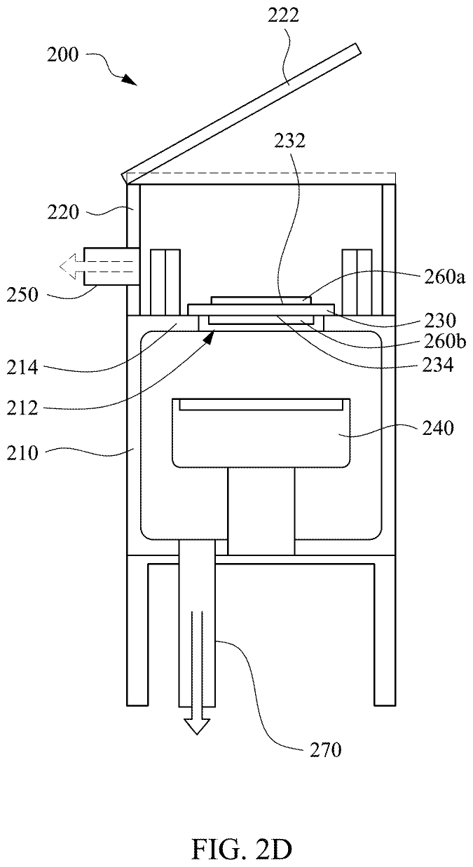

Referring to FIG. 2A through FIG. 2D, FIG. 2A through FIG. 2D are schematic diagrams showing a flow of a vacuum process method performed in a vacuum process apparatus in accordance with an embodiment of the present invention. In the present embodiment, a vacuum process apparatus 200 mainly includes a process chamber 210, a load lock 220, a carrier 230, a process device 240, and an evacuating device 250.

The process chamber 210 is configured to perform a vacuum process on objects to be treated, such as a first object 260a to be treated and a second object 260b to be treated. Accordingly, the process chamber 210 is usually under a vacuum state. In some examples, the vacuum process may be a deposition process or a coating process, for example, a plasma enhanced chemical vapor deposition (PECVD) process or an evaporation process. The objects to be treated, such as the first object 260a to be treated and the second object 260b to be treated, may be, for example, wafers or work pieces. The process chamber 210 includes an opening 212, in which the opening 212 is disposed in a sidewall 214 of the process chamber 210. In some exemplary examples, as shown in FIG. 2A, the sidewall 212 of the process chamber 210 is an upper sidewall. In some certain examples, the opening 212 of the process chamber 210 may be disposed in the other sidewall of the process chamber 210 than the upper sidewall.

The load lock 220 is configured for transporting and replacing of the objects to be treated, such as the first object 260a to be treated and the second object 260b to be treated. The load lock 220 is disposed on the sidewall 214 where the opening 212 of the process chamber 210 is located, and the process chamber 210 and the load lock 220 are respectively located on two opposite sides of the opening 212. The load lock 220 may include a door 222, in which the door 222 is disposed on a side of the load lock 220. When the door 222 is opened, the object to be treated on which a vacuum process has been performed can be loaded out of the load lock 220, and a next object to be treated by the vacuum process is loaded in the load lock 220. When the door 222 is closed, the load lock 220 is sealed, and an evacuating operation may be performed on the load lock 220.

The carrier 230 is reversibly disposed on the opening 212 of the process chamber 210, and the carrier 230 can cover the whole opening 212 to seal the process chamber 210. As shown in FIG. 2A, the carrier 230 includes a first carrying surface 232 and a second carrying surface 234, in which the first carrying surface 232 and the second carrying surface 234 are located on two opposite sides of the carrier 230. The first carrying surface 232 and the second carrying surface 234 of the carrier 230 are configured to respectively carry two objects to be treated, such as the first object to be treated 260a and the second to be treated 260b. The first object to be treated 260a and the second to be treated 260b are respectively fixed on the first carrying surface 232 and the second carrying surface 234. For example, the first object to be treated 260a and the second to be treated 260b may be respectively fixed on the first carrying surface 232 and the second carrying surface 234 by using electrostatic suction, vacuum suction, an adhesive, or an adhesive tape. As the carrier 230 is reversed, the first object to be treated 260a originally located within the process chamber 210 is reversed to the load lock 220, and the second to be treated 260b originally located within the load lock 220 is reversed to the process chamber 210. In some exemplary examples, in the reversing of the carrier 230, the carrier 230 is lifted up to separate the carrier 230 from the sidewall 214 of the process chamber 210 by a distance, in which the distance can provide a reversing space for the carrier 230. Then, the carrier 230 is reversed, and the carrier 230 is subsequently lowered to the sidewall 214 of the process chamber 210 to cover the opening 212.

Referring to FIG. 2A continuously, the process device 240 is disposed within the process chamber 210. The process device 240 is configured to provide chemical reactants, such as precursors for depositing or coating, within the process chamber 210. The chemical reactants may also include carrier gases of precursors. The chemical reactants may be gases, mixtures of gases and liquids, or mist liquids. In some exemplary examples, the process device 240 may be a deposition device, such as a plasma enhanced chemical vapor deposition device, or a coating device, such as an evaporation device.

The evacuating device 250 is connected to load lock 220. The evacuating device 250 can perform an evacuating operation on the load lock 220 to make the load lock 220 be in a vacuum state as the process chamber 210. In some examples, the evacuating device 250 is mainly configured to perform the evacuating operation on the load lock 220 while the vacuum process is performed within the process chamber 210.

In some exemplary examples, the vacuum process apparatus 200 may also include another evacuating device 270. The evacuating device 270 is connected to the process chamber 210. The evacuating device 270 can perform an evacuating operation on the process chamber 210. In some examples, the evacuating device 270 may perform an evacuating operation on the process chamber 210 before the vacuum process apparatus 200 goes onto operation, such that the process chamber 210 is in a vacuum state before the all vacuum processes are performed. In some other examples, the evacuating device 270 may also perform the evacuating operation on the process chamber 210 after the vacuum process apparatus 200 goes onto operation.

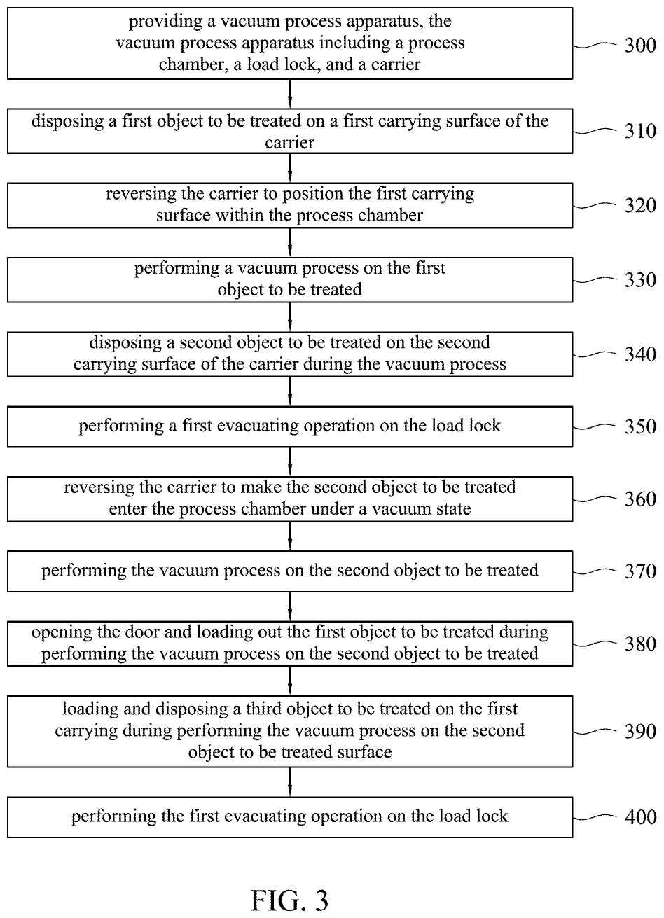

Referring to FIG. 2A through FIG. 2D and FIG. 3, in which FIG. 3 is a flow chart of a vacuum process method in accordance with an embodiment of this invention. A vacuum process may be performed by using the vacuum process apparatus 200. In some examples, the vacuum process method begins at operation 300, where a vacuum process apparatus is provided, in which the vacuum process apparatus mainly includes a process chamber, a load lock, and a carrier, and the configuration and the arrangement of the process chamber, the load lock, and the carrier may be similar to the aforementioned vacuum process apparatus. In some exemplary examples, the vacuum process method is performed in the vacuum process apparatus 200. The devices, and the arrangements and configurations of the devices are described above, and are not repeated herein.

Next, operation 310 is performed to dispose and fix a first object 260a to be treated on the carrier 230. In some examples, in the operation 310, the first carrying surface 232 of the carrier 230 is located within the load lock 220. Performing the operation 310 includes opening the door 222 of the load lock 220, loading the first object 260a to be treated into the load lock 220 through the door 222, and disposing and fixing the first object 260a to be treated on the first carrying surface 232 of the carrier 230. For example, the first object 260a to be treated may be fixed on the first carrying surface 232 of the carrier 230 by electrostatic attracting, vacuum attracting, or adhering.

Then, operation 320 is performed to reverse the carrier 230, so as to reverse the first carrying surface 232 of the carrier 230 and the first object 260a to be treated carried thereon into the process chamber 210. Simultaneously, the second carrying surface 234 of the carrier 230 is reversed into the load lock 220. In some exemplary examples, in the reversing of the carrier 230, the carrier 230 may be lifted up to form a space, which is required for reversing the carrier 230, between the carrier 230 and the sidewall 214 of the process chamber 210, the carrier 230 is then reversed, and the carrier 230 subsequently covers the sidewall 214 of the process chamber 210 with the first carrying surface 232 facing the process chamber 210 to seal the process chamber 210. Now, the first object 260a to be treated may face the process chamber 240.

After the first object 260a to be treated is disposed within the process chamber 210, operation 330 may be performed to perform the vacuum process on the first object 260a to be treated within the process chamber 210. The vacuum process may be a deposition process, such as a plasma enhanced chemical vapor deposition process. The vacuum process may also be a coating process, such as an evaporation process. In some exemplary examples, in the vacuum process of the first object 260a to be treated, a second evacuating operation may be firstly performed on the process chamber 210 by using the evacuating device 270 to make the process chamber 210 be in a vacuum state, and chemical reactants are subsequently provided by using the process device 240 to perform a vacuum process operation, such as a deposition operation or a coating operation, on the first object 260a to be treated. The chemical reactants provided by the process device 240 may be, for example, precursors for depositing or coating. The chemical reactants may also include carrier gases of precursors. The chemical reactants may be gases, liquids, or mixtures of gases and liquids.

Then, as shown in FIG. 2A, operation 340 may be performed to load a second object 260b to be treated into the load lock 220 and to dispose and fix the second object 260b to be treated on the second carrying surface 234 of the carrier 230 during the vacuum process of the first object 260a to be treated within the process chamber 210. Similarly, the second object 260b to be treated may be fixed on the second carrying surface 234 of the carrier 230 by electrostatic attracting, vacuum attracting, or adhering.

Then, as shown in FIG. 2B, operation 350 may be performed to close the door 222 of the load lock 220 to seal the load lock 220, and a first evacuating operation is performed on the load lock 220 by using the evacuating device 250 to make the load lock 220 be in a vacuum state as the process chamber 210. In some exemplary examples, the first evacuating operation is performed during the vacuum process of the first object 260a to be treated within the process chamber 210.

In some examples, loading the second object 260b to be treated into the load lock 220, disposing and fixing the second object 260b to be treated on the second carrying surface 234 of the carrier 234, and performing the first evacuating operation of the load lock 220 can be performed while the vacuum process of the first object 260a to be treated is performed within the process chamber 210, such that preparation of the second object 260b to be treated can be partly or completely finished during the vacuum process of the first object 260a to be treated. Accordingly, two sequential vacuum processes are performed more efficiently, thereby significantly reducing time of the entire process and effectively enhancing throughput.

As shown in FIG. 2C, after the vacuum process of the first object 260a to be treated is completed, operation 360 may be performed to reverse the carrier 230, so as to reverse the second object 260b to be treated into the process chamber 210 and to reverse the first object 260a to be treated into the load lock 220 while the load lock 220 and the process chamber 210 are in the same vacuum state.

The vacuum processes of all the objects to be treated are completed more efficiently by repeating the aforementioned operations.

For example, as shown in FIG. 2D, operation 370 may be performed to perform the vacuum process on the second object 260b to be treated within the process chamber 210. Similarly, in the vacuum process of the second object 260b to be treated, chemical reactants may be provided by using the process device 240 to perform a vacuum process operation, such as a deposition operation or a coating operation, on the second object 260b to be treated. Referring to FIG. 2D continuously, operation 380 may be performed to open the door 222 of the load lock 220 and to load out the first object 260a to be treated on which the vacuum process has been completed while the vacuum process is performed on the second object 260b to be treated within the process chamber 210. Then, operation 390 may be performed to load a next object to be treated (i.e. a third object to be treated) into the load lock 220, and to dispose and fix the third object to be treated on the first carrying surface 232 of the carrier 230 while the vacuum process of the second object 260b to be treated is performed within the process chamber 210. The opening of the door 222 of the load lock 220 has relieved the vacuum of the load lock 220, so operation 400 may be performed now to close the door 222 of the load lock 220 to seal the load lock 220, and to perform the first evacuating operation on the load lock 220 by using the evacuating device 250 to make the load lock 220 be in the same vacuum state as the process chamber 210 again.

According to the aforementioned embodiments, one advantage of the present invention is that the vacuum process apparatus of the present invention includes a reversibly carrier disposed between a process chamber and a load lock, and the carrier has two opposite carrying surfaces and can carry two objects to be treated simultaneously. Thus, when a vacuum process is performed on the object to be treated which is carried by one side of the carrier within the process chamber, the object to be treated on which the vacuum process is completed may be loaded out of the load lock, another object to be treated may be loaded into the load lock, and an evacuating operation may be performed on the load lock. Therefore, a preparation operation of a next object to be treated may be simultaneously performed during the vacuum process of one object to be treated, thereby greatly enhancing process efficiency and effectively increasing throughput.

Although the present invention has been described in considerable detail with reference to certain embodiments thereof, the foregoing embodiments of the present invention are illustrative of the present invention rather than limiting of the present invention. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. A vacuum process apparatus, comprising:
a process chamber having an opening;
a load lock disposed on the process chamber;
a carrier comprising a first carrying surface and a second carrying surface, which is opposite to the first carrying surface, wherein the carrier is reversibly disposed on the opening to seal the process chamber, to position one of the first carrying surface and the second carrying surface in the process chamber, and to position the other one of the first carrying surface and the second carrying surface in the load lock, and the first carrying surface and the second carrying surface are configured to respectively carry a first object to be treated and a second object to be treated;
a process device disposed within the process chamber and configured to provide chemical reactants within the process chamber; and
an evacuating device configured to perform an evacuating operation on the load lock while a vacuum process is performed within the process chamber.

2. The vacuum process apparatus of claim 1, wherein the load lock comprises a door disposed on a side of the load lock.

3. The vacuum process apparatus of claim 1, wherein the process device is a deposition device.

4. The vacuum process apparatus of claim 1, wherein the process device is an evaporation device.

5. A vacuum process method, comprising:
providing a vacuum process apparatus, the vacuum process apparatus comprising:
a process chamber having an opening;
a load lock disposed on the process chamber; and
a carrier comprising a first carrying surface and a second carrying surface, which is opposite to the first carrying surface, wherein the carrier is disposed to cover the opening to seal the process chamber;
disposing a first object to be treated on the first carrying surface;
reversing the carrier to position the first carrying surface within the process chamber;
performing a vacuum process on the first object to be treated within the process chamber;
disposing a second object to be treated on the second carrying surface during the vacuum process;
performing a first evacuating operation on the load lock; and
reversing the carrier to make the second object to be treated enter the process chamber under a vacuum state and to make the first object to be treated enter the load lock after the vacuum process is completed.

6. The vacuum process method of claim 5, wherein the load lock comprises a door disposed on a side of the load lock for the first object to be treated and the second object to be treated being loaded in and loaded out of the load lock.

7. The vacuum process method of claim 6, after reversing the carrier, the vacuum process method further comprising:
performing the vacuum process on the second object to be treated;
opening the door and loading out the first object to be treated during performing the vacuum process on the second object to be treated;
loading and disposing a third object to be treated on the first carrying surface during performing the vacuum process on the second object to be treated; and
performing the first evacuating operation on the load lock.

8. The vacuum process method of claim 5, wherein performing the vacuum process on the first object to be treated comprises:
performing a second evacuating operation on the process chamber; and
using a process device to provide chemical reactants.

9. The vacuum process method of claim 5, wherein the vacuum process is a deposition process.

10. The vacuum process method of claim 5, wherein the vacuum process is an evaporation process.
